(19) United States
(12) Patent Application Publication
(10) Pub. No.: US 2025/0338465 A1
(43) Pub. Date: Oct. 30, 2025

(54) METHOD AND MATERIAL SYSTEM FOR BACKSIDE POWER DELIVERY NETWORK IN STATIC RANDOM-ACCESS MEMORY DEVICES

(71) Applicant: Applied Materials, Inc., Santa Clara, CA (US)

(72) Inventors: Pratik B. Vyas, Fremont, CA (US); Gregory Costrini, Flanders, NJ (US); Ashish Pal, San Ramon, CA (US); El Mehdi Bazizi, San Jose, CA (US); Veeraraghavan S. Basker, Fremont, CA (US); Benjamin Colombeau, San Jose, CA (US); Balasubramanian Pranatharthiharan, San Jose, CA (US)

(73) Assignee: Applied Materials, Inc., Santa Clara, CA (US)

(21) Appl. No.: 18/650,831

(22) Filed: Apr. 30, 2024

(51) Int. Cl. H10B 10/00

(52) U.S. Cl. CPC H10B 10/12

(57) ABSTRACT

Methods and structure for static random-access memory (SRAM) devices with SRAM cells that have backside power delivery networks. A semiconductor device can include one or more static random-access memory cells. Each SRAM cell can include a backside power delivery network with a drain voltage rail and a source voltage rail. Each SRAM cell can also include a memory layer overlaying the backside power delivery network. The memory layer can implement an SRAM memory element. The drain voltage rail and the source voltage rail are connected to contacts at a top of the SRAM memory element. Each SRAM cell can also include a frontside layer overlaying the memory layer. The memory layer can include a word line and a bit line that are connected to the top of the SRAM memory element.

### TECHNICAL FIELD

The present technology relates to semiconductor systems, processes, and equipment. More specifically, the present technology relates to processes and structures for static random-access memory.

### BACKGROUND

Static random-access memory (SRAM) devices are used to store data while system power is supplied to the SRAM devices. SRAM cells can be arranged in arrays to form SRAM devices. Many computers use SRAM devices as cache memory because SRAM devices have relatively low power consumption and relatively good performance. Many Silicon-on-Chip (SoC) systems use SRAM devices because of the low power consumption of the SRAM devices to minimize limitations related to minimum operating voltage and standby leakage for the entire SoC system. Further improving the energy efficiency and response time for reads and writes to SRAM devices can greatly improve SoC systems.

Thus, there is a need for improved semiconductor structures and corresponding fabrication methods that can be used to increase the energy efficiency and response time for reads and writes in SRAM devices. These and other needs are addressed by the present technology.

### SUMMARY

In some embodiments, a semiconductor device may include one or more static random-access memory (SRAM) cells. Each of the one or more SRAM cells may include: a backside power delivery network comprising a drain voltage rail and a source voltage rail; a memory layer overlaying the backside power delivery network, wherein the memory layer implements an SRAM memory element, and wherein the drain voltage rail and the source voltage rail are connected to contacts at a top of the SRAM memory element; and a frontside layer overlaying the memory layer comprising a word line and a bit line that are connected to the top of the SRAM memory element.

In some embodiments, a method of forming a semiconductor device can include forming one or more static random-access memory (SRAM) cells. Forming each SRAM cell can include forming a memory layer, wherein the memory layer implements an SRAM memory element, wherein the SRAM memory element has contacts at a top of the SRAM memory element; forming a frontside layer overlaying a first surface of the memory layer, wherein the frontside layer comprising a word line and a bit line that are connected to the top of the SRAM memory element; and forming a backside power delivery network overlaying a second surface of the memory layer, wherein the backside power delivery network comprises a drain voltage rail and a source voltage rail that are connected to the contacts.

In some embodiments, a semiconductor device may include one or more static random-access memory (SRAM) cells. Each of the one or more SRAM cells may include: a backside power delivery network comprising a drain voltage rail and a source voltage rail; a memory layer overlaying the backside power delivery network, wherein the memory layer implements an SRAM memory element, and the drain voltage rail and the source voltage rail are connected to the SRAM memory element and provide power to the SRAM memory element; and a frontside layer overlaying the memory layer comprising a word line and a bit line that are connected to a top of the SRAM memory element.

In any embodiments, any and all of the following features may be implemented in any combination and without limitation. The semiconductor device can further include a first via that extends from the source voltage rail to a first contact of the contacts. The semiconductor device can further include a second via that extends from the drain voltage rail to a second contact of the contacts. The first via and the second via can be rectangular vias with a cross-sectional width of less than or about 20.0 nm. The first via and the second via can be square vias with a cross-sectional length of less than or about 20.0 nm. A capacitance between the source voltage rail and the word line can be between about 4.0 aF and about 80.0 aF. A capacitance between the source voltage rail and the word line can be less than or about 10.0 aF.

A capacitance between the drain voltage rail and the word line can be between about 1.0 aF and about 10.0 aF. A capacitance between the source voltage rail and the bit line can be between about 1.0 aF and about 10.0 aF. The semiconductor device can further include a bit line bar connected to contacts at a top of the SRAM memory element. A capacitance between the source voltage rail and the bit line bar can be less than or about 3.0 aF. The SRAM memory element can include at least six transistors. Forming the backside power delivery network can include forming a first via that extends from the source voltage rail to a first contact of the contacts. Forming the backside power delivery network can include forming a second via that extends from the drain voltage rail to a second contact of the contacts. Forming the memory layer can include forming a first placeholder via that extends from a bottom of the SRAM memory element to a first contact of the contacts. Forming the backside power delivery network can include forming a first via to replace the first placeholder via, wherein the first via extends from the source voltage rail to a first contact of the contacts.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a top plan view of one embodiment of a processing system of deposition, etching, baking, and curing chambers that may be included or configured according to some embodiments of the present technology.

FIG. 2 illustrates an example circuit diagram of a SRAM cell of an SRAM device according to some embodiments of the present technology.

FIG. 3 illustrates an example three-dimensional schematic of an SRAM cell with a backside power delivery network according to some embodiments of the present technology.

FIG. 4 illustrates an example schematic of multiple layers of the SRAM cell with a backside power delivery network according to some embodiments of the present technology.

FIG. 5 illustrates an example three-dimensional schematic 500 of an SRAM cell with a frontside power delivery network according to some embodiments of the present technology.

FIG. 6 illustrates an example circuit diagram of an SRAM device with an array of SRAM cells according to some embodiments of the present technology.

FIG. 7 illustrates an example flow diagram for fabricating an SRAM device according to some embodiments of the present technology.

FIGS. 8A-8D illustrate exemplary schematic cross-sectional structures produced according to some embodiments of the present technology.

FIGS. 9A-9C illustrate exemplary schematic cross-sectional structures produced according to some embodiments of the present technology.

### DETAILED DESCRIPTION

The present disclosure relates to structures within SRAM devices and the method of fabrication of these structures. In particular, the structure and method of fabrication of the SRAM cells of the SRAM devices is discussed herein. The SRAM cells described herein have a backside power-delivery network rather than a frontside power-delivery network. In this way, the drain voltage rail (which can be referred to as VDD) and the source voltage rail (which can be referred to as VSS) connected to each SRAM cell at the opposite side of the SRAM cell from where the bit lines (which can be referred to as BL) and the word line (which can be referred to as WL) connect to the SRAM cell. This structure of SRAM cell can decrease capacitances between important components. For example, the following capacitances can be decreased: 1) the capacitance between the source voltage rail and the word line, 2) the capacitance between drain voltage rail and the word line, 3) the capacitance between the source voltage rail and the bit line, and 4) the capacitance between the source voltage rail and the bit line bar (which can be referred to as BLBar). By decreasing the above capacitances, the operating speed of the individual SRAM cells, the arrays of SRAM cells, and the entire SRAM device can be increased. For example, the read and write delay times of the individual SRAM cells, the arrays of SRAM cells, and the entire SRAM device can be decreased by decreasing the above capacitances.

The structure of the SRAM cell with a backside power-delivery network can include vias from the source voltage rail and the drain voltage rail to the contacts of the SRAM memory elements. The SRAM cell can also include bit lines, bit line bars, and word lines. The SRAM memory elements can include different transistors and/or combinations of transistors. For example, the SRAM memory elements can be six transistor SRAM memory elements. The SRAM memory elements store the data bits and/or the state to be read to indicate the data. The above vias of the backside power-delivery network can have a limited cross sectional width and length in order to fit within certain dimensions within the SRAM cell based on the layout of the SRAM cell as described herein.

Although the remaining disclosure will routinely identify specific processes utilizing the disclosed technology, it will be readily understood that the systems and methods are equally applicable to a variety of other processes as may occur in the described chambers. Accordingly, the technology should not be considered to be so limited as for use with the described etching or deposition processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems.

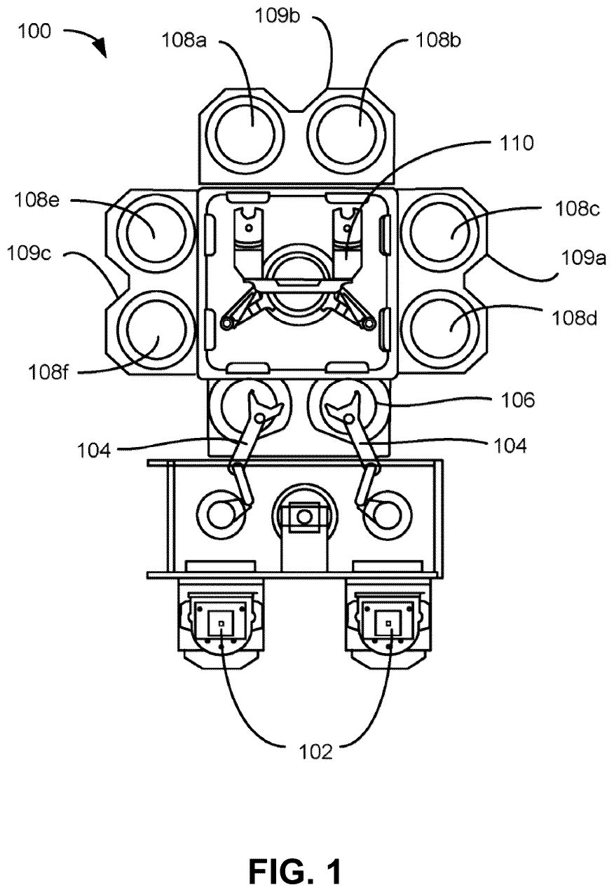

FIG. 1 illustrates a top plan view of one embodiment of a processing system 100 of deposition, etching, baking, and curing chambers that may be included or configured according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

System 100, or more specifically chambers incorporated into system 100 or other processing systems, may be used to produce structures according to some embodiments of the present technology.

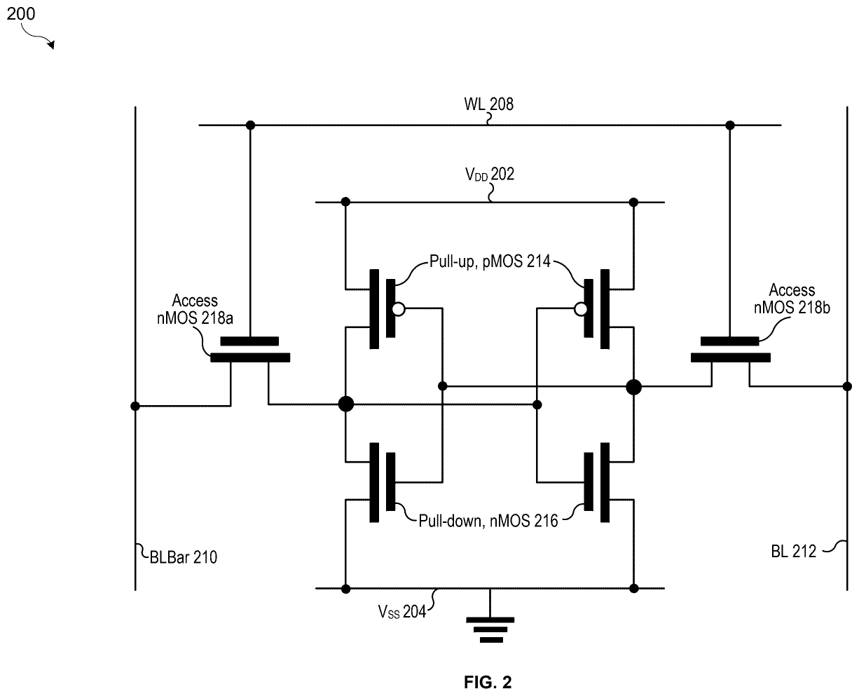

FIG. 2 illustrates an example circuit diagram 200 of an SRAM cell of an SRAM device. This example SRAM cell is a six-transistor circuit with a drain voltage rail 202 (which can be referred to as VDD) and a source voltage rail 204 (which can be referred to as VSS). The SRAM cell can also include other types of SRAM cell designs such as an eight-transistor circuit. The SRAM cell can be connected to a word line 208, a bit line 212, and a bit line bar 210. The word line 208, bit line 212, and the bit line bar 210 can be used to read and write information (for example, a bit with a value of 1 or 0). The six-transistor cell can include pMOS transistors 214 which can be referred to as pull-up transistors. The six-transistor cell can include nMOS transistors 216 which can be referred to as pull-down transistors. The six-transistor cell can include nMOS transistors 218a, 218b which can be referred to as access nMOS transistors. As described herein, the SRAM cell can be fabricated (for example, manufactured) with a backside power delivery network that places the drain voltage rail 202 and the source voltage rail 204 on the backside (also referred to as bottom) of the SRAM cell while the word line 208, the bit line 212, and the bit line bar 210 are placed on the frontside (also referred to as the top) of the SRAM cell. Having a backside power delivery network and frontside word line 208, bit line 212, and bit line bar 210 can reduce the capacitance between 1) the source voltage rail and the word line, 2) the drain voltage rail and the word line, 3) the source voltage rail and the bit line, and 4) the source voltage rail and the bit line bar. The reduction of these capacitances can increase the operating speed of the individual SRAM cell, an array of SRAM cells, and an SRAM device by reducing read and write delay times.

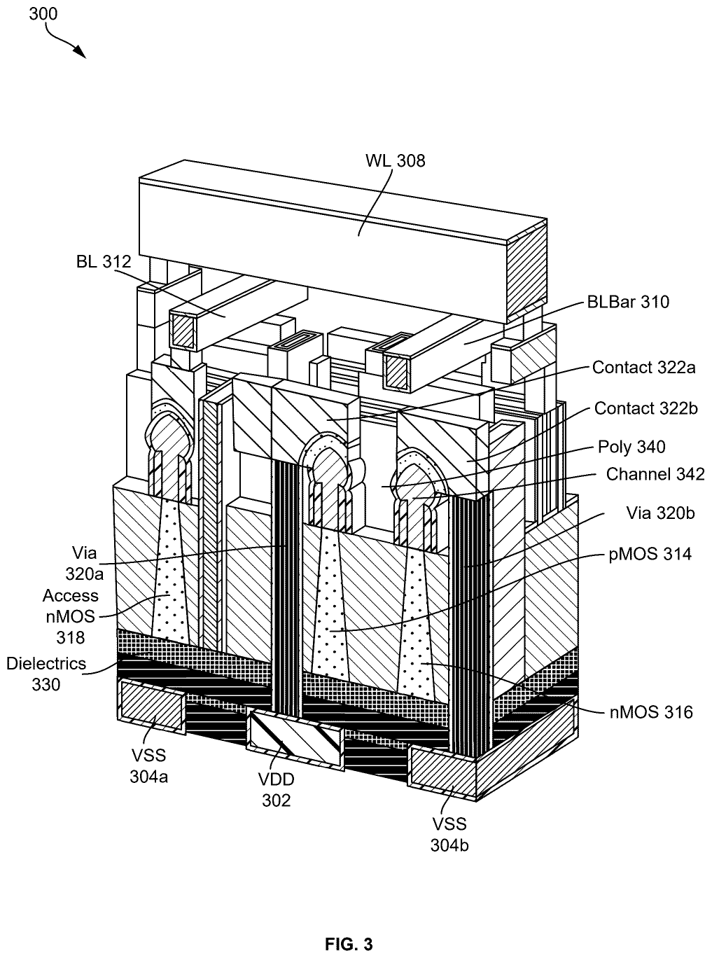

FIG. 3 illustrates an example three-dimensional schematic 300 of an SRAM cell with a backside power delivery network. The backside power delivery network includes the VDD 302 (for example, the drain voltage rail 202 of FIG. 2) and the VSS 304a, 304b (for example, the source voltage rail 204 of FIG. 2). As described herein, the VDD 302 can also be referred to as the drain voltage rail 302 and the VSS 304a, 304b can also be referred to as the source voltage rail(s) 304a, 304b. The backside power delivery network can refer to the drain voltage rail 302 and the source voltage rail(s) 304a, 304b being on the backside of the substrate 330 on which the structures of the SRAM cell are deposited and etched. One or more dielectric materials 330 can be used as layers to separate the VSS 304a, 304b and the VDD 302 from the pMOS transistor 314 and the nMOS transistor 316. FIG. 3 illustrates two types of dielectric materials, but any combination of one or more dielectric materials 330 can be suitable. Additionally, in this example, the substrate on which the SRAM cell was originally built has been removed in order to add the VSS 304a, 304b, the VDD 302, and the one or more dielectric materials 330. Instead, the VDD 302 can be connected to the pMOS transistor 314 (for example, the pMOS transistor 214 of FIG. 2) by a contact 322a and a via 320a. The VSS 304b can be connected to the nMOS transistor 316 (for example, the nMOS transistor 216 of FIG. 2) by a contact 322b and a via 320b. Many components of the SRAM cell are connected by the use of contacts such as contact 322a and 322b as seen in FIG. 3. The pMOS transistor 314 can be connected to a gate which is in turn connected via a contact to the bit line bar 310. Likewise, the nMOS transistor 316 can be connected to the gate. The access nMOS transistor 318 (for example, the access nMOS transistors 218a, 218b of FIG. 2) can be connected to the bit line 312 and the via 320a.

The poly 340 can be the dummy gate covering the channels of nMOS transistor 316 and the pMOS transistor 314 and can be separated from them by a thin layer of gate oxide. Similarly, the access nMOS 318 can be connected to the poly 340 which in turn can be connected to the word line 308. Possible material for the poly 340 can be a dielectric material such as a polysilicon material. The nMOS transistor 316, the pMOS transistor 314, and the access nMOS 318 can be dielectric materials such as semiconductor materials like Silicon, Germanium, Silicon-Germanium, etc. The combination of the poly 340 and nMOS transistor 316 can be referred to as the nMOS transistor structure. Similarly, the combination of the poly 340 and the pMOS transistor 314 can be referred to as the pMOS transistor structure.

The access nMOS 318, the nMOS transistor 316, the pMOS transistor 314, the contacts 322a, 322b, the poly 340, and the channel 342 can be referred to as portions of the SRAM memory element of the SRAM memory cell. Similarly, the access nMOS 318, the nMOS transistor 316, the pMOS transistor 314, the contacts 322a, 322b, the poly 340, and the channel 342 can be referred to as parts of the memory layer of the SRAM memory cell. In some examples, the channel 342 can be a component of the nMOS transistor 316 and the pMOS transistor 314. The vias 320a, 320b can also be referred to as parts of the memory layer of the SRAM memory cell, but are not portions of the SRAM memory element. Instead the vias 320a, 320b can be referred to as part of the backside power delivery network connecting the VDD 302 and the VSS 304a, 304b to the SRAM memory element (for example, the contacts 322a, 322b).

The bit line 312, the word line 308, and the bit line bar 310 can be made of a conductive material. Any conductive material suitable for electronic wires can be used. For example, conductive materials can include copper, gold, graphene, tungsten, a composite, an alloy, or other conductive materials. The bit line 312, the word line 308, and the bit line bar 310 can be made of any combination of the same material or different materials. The vias 320a, 322b can also be made of a conductive material. In some examples, the vias 320a, 322b can be the same material as any one or more of the bit line 312, the word line 308, and the bit line bar 310. In some examples, the vias 320a, 322b can be a different material from the bit line 312, the word line 308, and the bit line bar 310. Similarly, the VDD 302 and the VSS 304a, 304b can be made of a conductive material. In some examples, the VDD 302 and the VSS 304a, 304b can be the same material as any one or more of the bit line 312, the word line 308, and the bit line bar 310. In some examples, the VDD 302 and the VSS 304a, 304b can be a different material from the bit line 312, the word line 308, and the bit line bar 310.

By fabricating the SRAM cell with a backside power delivery network including the VDD 302 and the VSS 304a, 304b to be on the backside of the SRAM cell, important capacitances for the function of the SRAM cell can be reduced and thus the operating speed of the SRAM cell can be increased. These capacitances that can be reduced can include: 1) the capacitance between the source voltage rail and the word line, 2) the capacitance between drain voltage rail and the word line, 3) the capacitance between the source voltage rail and the bit line, and 4) the capacitance between the source voltage rail and the bit line bar. The bit line, the bit line bar, and the write line can be referred to as the frontside layer of the SRAM cell.

In some examples, the capacitance between the source voltage rail and the word line can be characterized as 80.0 aF (attofarads) or less. In some examples, the capacitance between the source voltage rail and the word line can be characterized as about or less than 80.0 aF, about or less than 79.5 aF, about or less than 79.0 aF, about or less than 78.5 aF, about or less than 78.0 aF, about or less than 77.5 aF, about or less than 77.0 aF, about or less than 76.5 aF, about or less than 76.0 aF, about or less than 75.5 aF, about or less than 75.0 aF, about or less than 74.5 aF, about or less than 74.0 aF, about or less than 73.5 aF, about or less than 73.0 aF, about or less than 72.5 aF, about or less than 72.0 aF, about or less than 71.5 aF, about or less than 71.0 aF, about or less than 70.5 aF, about or less than 70.0 aF, about or less than 69.5 aF, about or less than 69.0 aF, about or less than 68.5 aF, about or less than 68.0 aF, about or less than 67.5 aF, about or less than 67.0 aF, about or less than 66.5 aF, about or less than 66.0 aF, about or less than 65.5 aF, about or less than 65.0 aF, about or less than 64.5 aF, about or less than 64.0 aF, about or less than 63.5 aF, about or less than 63.0 aF, about or less than 62.5 aF, about or less than 62.0 aF, about or less than 61.5 aF, about or less than 61.0 aF, about or less than 60.5 aF, about or less than 60.0 aF, about or less than 59.5 aF, about or less than 59.0 aF, about or less than 58.5 aF, about or less than 58.0 aF, about or less than 57.5 aF, about or less than 57.0 aF, about or less than 56.5 aF, about or less than 56.0 aF, about or less than 55.5 aF, about or less than 55.0 aF, about or less than 54.5 aF, about or less than 54.0 aF, about or less than 53.5 aF, about or less than 53.0 aF, about or less than 52.5 aF, about or less than 52.0 aF, about or less than 51.5 aF, about or less than 51.0 aF, about or less than 50.5 aF, about or less than 50.0 aF, about or less than 49.5 aF, about or less than 49.0 aF, about or less than 48.5 aF, about or less than 48.0 aF, about or less than 47.5 aF, about or less than 47.0 aF, about or less than 46.5 aF, about or less than 46.0 aF, about or less than 45.5 aF, about or less than 45.0 aF, about or less than 44.5 aF, about or less than 44.0 aF, about or less than 43.5 aF, about or less than 43.0 aF, about or less than 42.5 aF, about or less than 42.0 aF, about or less than 41.5 aF, about or less than 41.0 aF, about or less than 40.5 aF, about or less than 40.0 aF, about or less than 39.5 aF, about or less than 39.0 aF, about or less than 38.5 aF, about or less than 38.0 aF, about or less than 37.5 aF, about or less than 37.0 aF, about or less than 36.5 aF, about or less than 36.0 aF, about or less than 35.5 aF, about or less than 35.0 aF, about or less than 34.5 aF, about or less than 34.0 aF, about or less than 33.5 aF, about or less than 33.0 aF, about or less than 32.5 aF, about or less than 32.0 aF, about or less than 31.5 aF, about or less than 31.0 aF, about or less than 30.5 aF, about or less than 30.0 aF, about or less than 29.5 aF, about or less than 29.0 aF, about or less than 28.5 aF, about or less than 28.0 aF, about or less than 27.5 aF, about or less than 27.0 aF, about or less than 26.5 aF, about or less than 26.0 aF, about or less than 25.5 aF, about or less than 25.0 aF, about or less than 24.5 aF, about or less than 24.0 aF, about or less than 23.5 aF, about or less than 23.0 aF, about or less than 22.5 aF, about or less than 22.0 aF, about or less than 21.5 aF, about or less than 21.0 aF, about or less than 20.5 aF, about or less than 20.0 aF, about or less than 19.5 aF, about or less than 19.0 aF, about or less than 18.5 aF, about or less than 18.0 aF, about or less than 17.5 aF, about or less than 17.0 aF, about or less than 16.5 aF, about or less than 16.0 aF, about or less than 15.5 aF, about or less than 15.0 aF, about or less than 14.5 aF, about or less than 14.0 aF, about or less than 13.5 aF, about or less than 13.0 aF, about or less than 12.5 aF, about or less than 12.0 aF, about or less than 11.5 aF, about or less than 11.0 aF, about or less than 10.5 aF, about or less than 9.5 aF, about or less than 9.0 aF, about or less than 8.5 aF, about or less than 8.0 aF, about or less than 7.5 aF, about or less than 7.0 aF, about or less than 6.5 aF, about or less than 6.0 aF, about or less than 5.5 aF, about or less than 5.0 aF, about or less than 4.5 aF, about or less than 4.0 aF, or less.

The improvement of the capacitance between the source voltage rail and the word line for a backside power delivery network SRAM cell, when compared to a frontside power delivery network SRAM cell, can be about a 70% improvement, about a 75% improvement, about an 80% improvement, about an 85% improvement, about a 90% improvement, or about a 95% improvement. Typically, the improvement of the capacitance between the source voltage rail and the word line for a backside power delivery network SRAM cell, when compared to a frontside power delivery network SRAM cell, can be between 70-95% improvement.

In some examples, the capacitance between drain voltage rail and the word line can be characterized as 20.0 aF (attofarads) or less. In some examples, the capacitance between drain voltage rail and the word line can be characterized as about or less than 20.0 aF, about or less than 19.5 aF, about or less than 19.0 aF, about or less than 18.5 aF, about or less than 18.0 aF, about or less than 17.5 aF, about or less than 17.0 aF, about or less than 16.5 aF, about or less than 16.0 aF, about or less than 15.5 aF, about or less than 15.0 aF, about or less than 14.5 aF, about or less than 14.0 aF, about or less than 13.5 aF, about or less than 13.0 aF, about or less than 12.5 aF, about or less than 12.0 aF, about or less than 11.5 aF, about or less than 11.0 aF, about or less than 10.5 aF, about or less than 10.0 aF, about or less than 9.5 aF, about or less than 9.0 aF, about or less than 8.5 aF, about or less than 8.0 aF, about or less than 7.5 aF, about or less than 7.0 aF, about or less than 6.5 aF, about or less than 6.0 aF, about or less than 5.5 aF, about or less than 5.0 aF, about or less than 4.5 aF, about or less than 4.0 aF, about or less than 3.5 aF, about or less than 3.0 aF, about or less than 2.5 aF, about or less than 2.0 aF, about or less than 1.5 aF, about or less than 1.0 aF, or less. The improvement of the capacitance between the drain voltage rail and the word line for a backside power delivery network SRAM cell, when compared to a frontside power delivery network SRAM cell, can be about a 50% improvement, about a 55% improvement, about a 60% improvement, about a 65% improvement, or about a 70% improvement. Typically, the improvement of the capacitance between the drain voltage rail and the word line for a backside power delivery network SRAM cell, when compared to a frontside power delivery network SRAM cell, can be between 50-70% improvement.

In some examples, the capacitance between the source voltage rail and the bit line can be characterized as 10.0 aF (attofarads) or less. In some examples, the capacitance between the source voltage rail and the bit line can be characterized as about or less than 10.0 aF, about or less than 9.5 aF, about or less than 9.0 aF, about or less than 8.5 aF, about or less than 8.0 aF, about or less than 7.5 aF, about or less than 7.0 aF, about or less than 6.5 aF, about or less than 6.0 aF, about or less than 5.5 aF, about or less than 5.0 aF, about or less than 4.5 aF, about or less than 4.0 aF, about or less than 3.5 aF, about or less than 3.0 aF, about or less than 2.5 aF, about or less than 2.0 aF, about or less than 1.5 aF, about or less than 1.0 aF, or less. The improvement of the capacitance between the source voltage rail and the bit line for a backside power delivery network SRAM cell, when compared to a frontside power delivery network SRAM cell, can be about a 40% improvement, about a 45% improvement, about a 50% improvement, about a 55% improvement, or about a 60% improvement. Typically, the improvement of the capacitance between the source voltage rail and the bit line for a backside power delivery network SRAM cell, when compared to a frontside power delivery network SRAM cell, can be between 40-60% improvement.

In some examples, the capacitance between the source voltage rail and the bit line bar can be characterized as 10.0 aF (attofarads) or less. In some examples, the source voltage rail and the bit line bar can be characterized as about or less than 10.0 aF, about or less than 9.5 aF, about or less than 9.0 aF, about or less than 8.5 aF, about or less than 8.0 aF, about or less than 7.5 aF, about or less than 7.0 aF, about or less than 6.5 aF, about or less than 6.0 aF, about or less than 5.5 aF, about or less than 5.0 aF, about or less than 4.5 aF, about or less than 4.0 aF, about or less than 3.5 aF, about or less than 3.0 aF, about or less than 2.5 aF, about or less than 2.0 aF, about or less than 1.5 aF, about or less than 1.0 aF, or less. The improvement of the capacitance between the source voltage rail and the bit line bar for a backside power delivery network SRAM cell, when compared to a frontside power delivery network SRAM cell, can be about a 40% improvement, about a 45% improvement, about a 50% improvement, about a 55% improvement, or about a 60% improvement. Typically, the improvement of the capacitance between the source voltage rail and the bit line bar for a backside power delivery network SRAM cell, when compared to a frontside power delivery network SRAM cell, can be between 40-60% improvement.

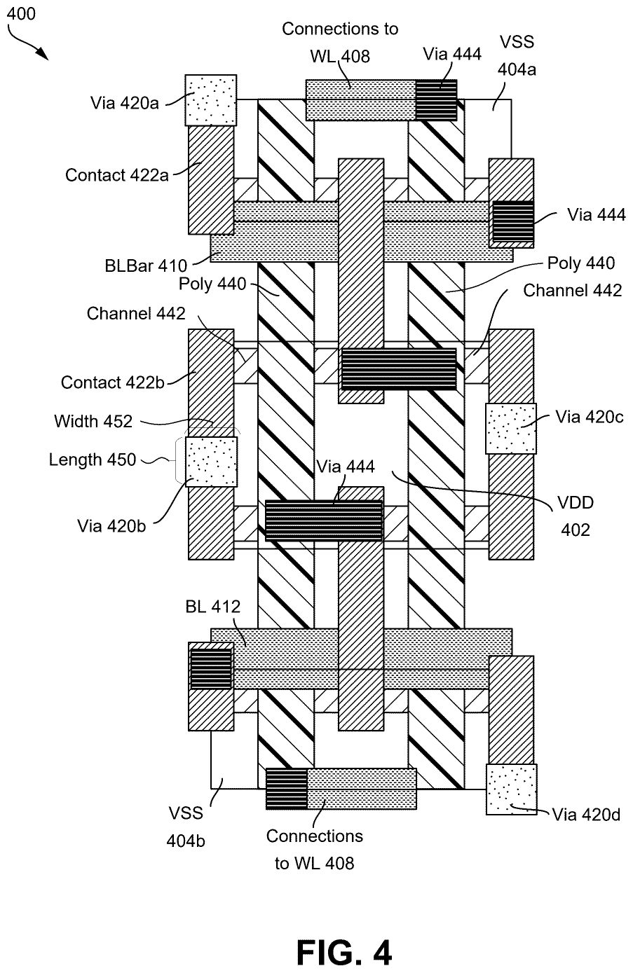

The three-dimensional schematic 300 is symmetrical (for example, as shown in FIG. 3 and FIG. 4) such that the same structures on the visible side of the three-dimensional schematic 300 are also on the hidden side opposite of the visible side of the three-dimensional schematic 300. For example, the hidden side has an equivalent set of vias 320a, 320b, contacts 322a, 322b, pMOS transistor 314, nMOS transistor 316, and access nMOS transistor 318.

Liners can be used in various portions of the SRAM device in order to prevent direct connection between certain conductive materials used in the vias 320a, 320b, the contacts 322a, 322b, the word line 308, the bit line 312, the bit line bar 310, the VDD 302, and the VSS 304a, 304b from contacting dielectric materials. Liners can be used to prevent diffusion of ions between dielectric materials and certain conductive materials. Any suitable liner material can be used. For example, tantalum, tantalum nitride, titanium, and titanium nitride can be used. In some examples, the liner can include multiple layers of different materials.

FIG. 4 illustrates an example schematic 400 of multiple layers of the SRAM cell with a backside power delivery network. The backside power delivery network includes the VDD 402 (for example, the VDD 202 of FIG. 2) and the VSS 404a, 404b (for example, the Vin 204 and Vout 206 of FIG. 2). In FIG. 4, the VDD 402 and VSS 404a, 404b are outlined to show their approximate position below the layers shown in FIG. 4. The schematic 400 shows the m0 layer (which can also be referred to as the first metal layer or the zero-eth metal layer) with the bit line 412, the bit line bar 410, and connections up to the write line 408 (not actually pictured in FIG. 4). The schematic 400 also shows contacts (for example, contacts 422a, 422b) and dielectrics for the memory layer of the SRAM cell. The vias 420a, 420b, 420c, 420d are the vias connecting the backside power delivery network (for example, the VDD 402 and VSS 404a, 404b) to their respective contacts 422a, 422b and thus to the bit line 412, the bit line bar 410, and the poly 440. The poly 440 serves as the gate for the transistors. Other vias 442 connect the m0 layer to the m1 layer.

The vias 420a, 420b, 420c, 420d can have cross-sections with a width (for example, the width 452 of via 420b) and length (for example, length 450 of via 420b). In some examples, the width of the vias can be about or less than a maximum width. For example, the vias 420a, 420b, 420c, 420d can have a maximum width determined in relation to a liner and/or other buffering layers between the vias 420a, 420b, 420c, 420d and the poly 440. In some examples, the maximum width of the vias 420a, 420b, 420c, 420d can be 20.0 nm or less. In some examples, the maximum width of the vias about or less than 20.0 nm, about or less than 19.0 nm, about or less than 18.0 nm, about or less than 17.0 nm, about or less than 16.0 nm, about or less than 15.0 nm, about or less than 14.0 nm, about or less than 13.0 nm, about or less than 12.0 nm, about or less than 11.0 nm, about or less than 10.0 nm, about or less than 9.0 nm, about or less than 8.0 nm, about or less than 7.0 nm, about or less than 6.0 nm, about or less than 5.0 nm, or less. In some examples, the width of the vias 420a, 420b, 420c, 420d can be the maximum width.

In some examples, the length of the vias can be a maximum length. Similarly, the vias 420a, 420b, 420c, 420d can have a maximum length determined in relation to a liner and/or other buffering layers between the vias 420a, 420b, 420c, 420d and the channel 442. In some examples, the maximum length of the vias 420a, 420b, 420c, 420d can be 20.0 nm or less. In some examples, the maximum length of the vias about or less than 20.0 nm, about or less than 19.0 nm, about or less than 18.0 nm, about or less than 17.0 nm, about or less than 16.0 nm, about or less than 15.0 nm, about or less than 14.0 nm, about or less than 13.0 nm, about or less than 12.0 nm, about or less than 11.0 nm, about or less than 10.0 nm, about or less than 9.0 nm, about or less than 8.0 nm, about or less than 7.0 nm, about or less than 6.0 nm, about or less than 5.0 nm, or less. In some examples, the length of the vias 420a, 420b, 420c, 420d can be the maximum length.

The poly 440 can serve as the gate for the transistors of the SRAM cell. In some examples, the vias 420a, 420b, 420c, 420d are rectangular vias such that the cross section of the via is a rectangle. In some examples, the vias 420a, 420b, 420c, 420d are square vias such that the cross section of the via is a square. The vias 420a, 420b, 420c, 420d can have a maximum width. For example, the vias 420a, 420b, 420c, 420d can be wide enough to leave room for a liner and/or other buffering layers between the vias 420a, 420b, 420c, 420d and the poly 440. The poly 440 can serve as the gate for the transistors of the SRAM cell.

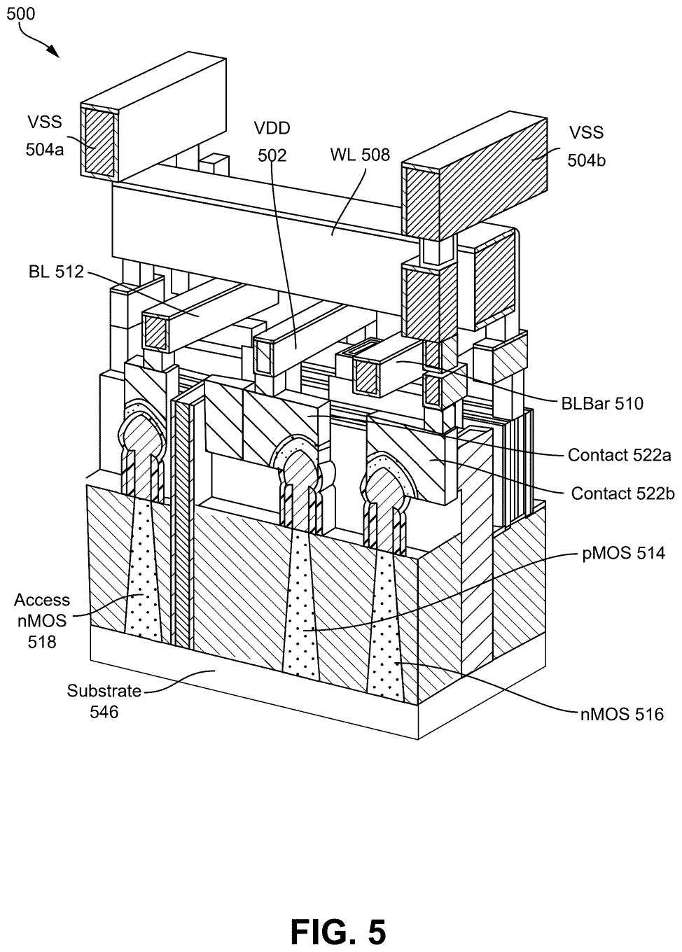

FIG. 5 illustrates an example three-dimensional schematic 500 of an SRAM cell with a frontside power delivery network. The frontside power delivery network can be positioned on the frontside (also referred to as the top) of the SRAM cell including the VDD 502 and the VSS 504a, 504b. The frontside power delivery network can also be considered the frontside because the frontside is the opposite side from the side facing the substrate 546. Here, the VDD 502 and the VSS 504a, 504b are much closer to the bit line 512, the bit line bar 510, and the word line 508. The result of having the VDD 502 and the VSS 504a, 504b are much closer to the bit line 512, the bit line bar 510, and the word line 508 can be increased capacitances between these various lines and rails. The increased capacitances can increase operating speeds of the SRAM cell, an array of SRAM cells, and the overall SRAM device. Similar to FIG. 3, the VDD 502 can be connected to the pMOS transistor 514 by a contact 522a. The VSS 504b can be connected to the nMOS transistor 516 by a contact 522b. The pMOS transistor 514 can be connected to a gate which is in turn connected via a contact to the bit line bar 510. Likewise, the nMOS transistor 516 can be connected to the gate. The access nMOS transistor 518 can be connected to the bit line 512.

An SRAM cell with a frontside power delivery network can have important capacitances with higher values when compared to the backside power delivery network SRAM cell of FIG. 3. Higher value capacitances can lead to higher read and write delays which can negatively reduce the operating speed of the SRAM. These important capacitances can include 1) the capacitance between the source voltage rail and the word line, 2) the capacitance between drain voltage rail and the word line, 3) the capacitance between the source voltage rail and the bit line, and 4) the capacitance between the source voltage rail and the bit line bar.

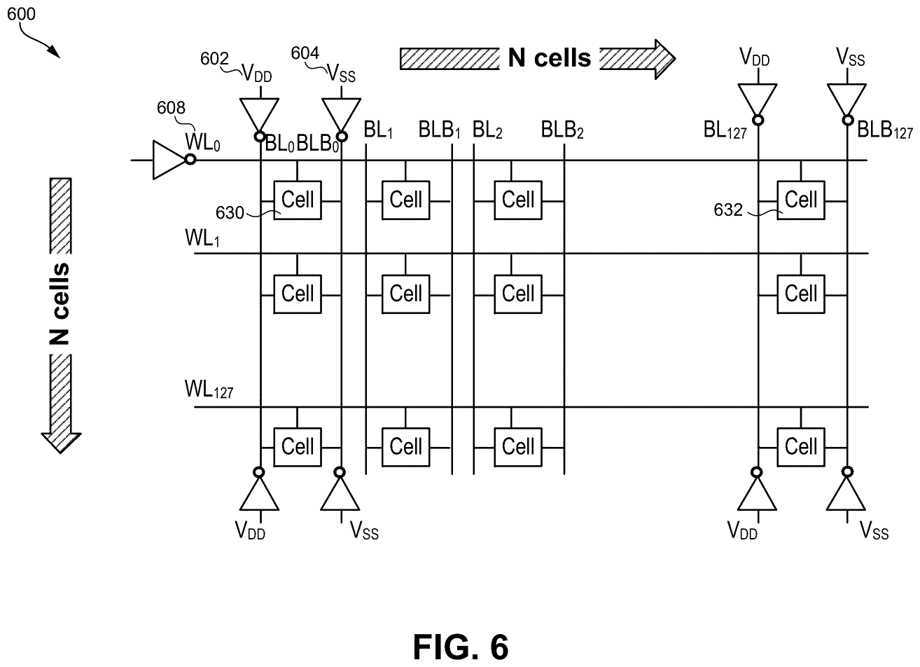

FIG. 6 illustrates an example block schematic 600 of an array of SRAM cells in an SRAM device. Each SRAM cells (for example, the SRAM cell of FIG. 2) can be connected to a word line 608 (for example, the word line 208 of FIG. 2) and a VDD 602 (for example, the VDD 302 of FIG. 3) and VSS 604 (for example, the VSS 304a, 304b of FIG. 3). The VDD and VSS lines can run perpendicularly to the word lines. Additionally, bit lines (labeled BL) and bit line bars (labeled BLB) can be shown in the array of SRAM cells. The array of SRAM cells can be used to store any number of bits (as a single SRAM cell represents a single bit of information).

In some examples, the array can be a 32×32 array of SRAM cells. In some examples, the array can be a 64×64 array of SRAM cells. In some examples, the array can be a 128×128 array of SRAM cells. In some examples, the array can be a 256×256 array of SRAM cells. The number of arrays in a row and/or column can be any number, especially numbers that are powers of 2. In some examples, the array can be significantly more than a 256×256 array of SRAM cells.

Read and write delays for SRAM devices can be measured for the near SRAM cell 630 and a far SRAM cell 632. Generally, read and write delays measured at the near SRAM cell 620 and the far SRAM cell 632 can be lower when each SRAM cell has a backside power delivery network (also referred to as BS-PDN) as compared to when each SRAM cell has a frontside power delivery network (also referred to as FS-PDN). Similarly, larger arrays of SRAM cells can have larger read and write delays than smaller arrays of SRAM cells. The benefits for operating speed of SRAM devices with SRAM cells using backside power delivery networks increases as the arrays of SRAM cells get larger.

For example, in a 32×32 SRAM array, the read delay for a near cell 630 of a FS-PDN SRAM cell and a BS-PDN SRAM cell may both be about equivalent at 30 ps. In a 64×64 SRAM array, the read delay for a near cell 630 of a FS-PDN SRAM cell can be about 60 ps while the read delay for a BS-PDN SRAM cell can be about 58.5 ps. In a 64×64 SRAM array, the read delay for a near cell 630 for a BS-PDN SRAM cell can have about −2% shorter read delay when compared to a FS-PDN SRAM cell. In a 128×128 SRAM array, the read delay for a near cell 630 of a FS-PDN SRAM cell can be about 120 ps while the read delay for a BS-PDN SRAM cell can be about 115 ps. In a 128×128 SRAM array, the read delay for a near cell 630 for a BS-PDN SRAM cell can have about −2% shorter read delay when compared to a FS-PDN SRAM cell. In a 256×256 SRAM array, the read delay for a near cell 630 of a FS-PDN SRAM cell can be about 260 ps while the read delay for a BS-PDN SRAM cell can be about 250 ps. In a 256×256 SRAM array, the read delay for a near cell 630 for a BS-PDN SRAM cell can have about −2% shorter read delay when compared to a FS-PDN SRAM cell. In some examples, the read delay for a near cell 630 for a BS-PDN SRAM cell of any size, when compared to an equivalent FS-PDN SRAM cell, can have about −2% or less shorter read delay, about −3% or less shorter read delay, about −4% or less shorter read delay, about −5% or less shorter read delay, about −6% or less shorter read delay, about −7% or less shorter read delay, about −8% or less shorter read delay, about −9% or less shorter read delay, or about −10% or less shorter read delay.

In another example, in a 32×32 SRAM array, the read delay for a far cell 632 of a FS-PDN SRAM cell and a BS-PDN SRAM cell may both be about equivalent at 30 ps. In a 64×64 SRAM array, the read delay for a far cell 632 of a FS-PDN SRAM cell can be about 60 ps while the read delay for a BS-PDN SRAM cell can be about 58.5 ps. In a 64×64 SRAM array, the read delay for a far cell 632 for a BS-PDN SRAM cell can have about −2% shorter read delay when compared to a FS-PDN SRAM cell. In a 128×128 SRAM array, the read delay for a far cell 632 of a FS-PDN SRAM cell can be about 120 ps while the read delay for a BS-PDN SRAM cell can be about 115 ps. In a 128×128 SRAM array, the read delay for a far cell 632 for a BS-PDN SRAM cell can have about −3% shorter read delay when compared to a FS-PDN SRAM cell. In a 256×256 SRAM array, the read delay for a far cell 632 of a FS-PDN SRAM cell can be about 260 ps while the read delay for a BS-PDN SRAM cell can be about 250 ps. In a 256×256 SRAM array, the read delay for a far cell 632 for a BS-PDN SRAM cell can have about −3.4% shorter read delay when compared to a FS-PDN SRAM cell. In some examples, the read delay for a far cell 632 for a BS-PDN SRAM cell of any size, when compared to an equivalent FS-PDN SRAM cell, can have about −2% or less shorter read delay, about −3% or less shorter read delay, about −4% or less shorter read delay, about −5% or less shorter read delay, about −6% or less shorter read delay, about −7% or less shorter read delay, about −8% or less shorter read delay, about −9% or less shorter read delay, or about −10% or less shorter read delay.

In another example, in a 32×32 SRAM array, the write delay for a near cell 630 of a FS-PDN SRAM cell and a BS-PDN SRAM cell may both be about equivalent at 45 ps. In a 64×64 SRAM array, the write delay for a near cell 630 of a FS-PDN SRAM cell can be about 55 ps while the write delay for a BS-PDN SRAM cell can be about 54 ps. In a 64×64 SRAM array, the write delay for a near cell 630 for a BS-PDN SRAM cell can have about −2% shorter write delay when compared to a FS-PDN SRAM cell. In a 128×128 SRAM array, the write delay for a near cell 630 of a FS-PDN SRAM cell can be about 75 ps while the write delay for a BS-PDN SRAM cell can be about 70 ps. In a 128×128 SRAM array, the write delay for a near cell 630 for a BS-PDN SRAM cell can have about −3% shorter write delay when compared to a FS-PDN SRAM cell. In a 256×256 SRAM array, the write delay for a near cell 630 of a FS-PDN SRAM cell can be about 110 ps while the write delay for a BS-PDN SRAM cell can be about 100 ps. In a 256×256 SRAM array, the write delay for a near cell 630 for a BS-PDN SRAM cell can have about −12% shorter write delay when compared to a FS-PDN SRAM cell. In some examples, the write delay for a near cell 630 for a BS-PDN SRAM cell of any size, when compared to an equivalent FS-PDN SRAM cell, can have about −7% or less shorter write delay, about −8% or less shorter write delay, about −9% or less shorter write delay, about −10% or less shorter write delay, about −11% or less shorter write delay, about −12% or less shorter write delay, about −13% or less shorter write delay, about −14% or less shorter write delay, about −15% or less shorter write delay, about −16% or less shorter write delay, about −17% or less shorter write delay, about −18% or less shorter write delay, about −19% or less shorter write delay, about −20% or less shorter write delay, about −21% or less shorter write delay, about −22% or less shorter write delay, about −23% or less shorter write delay, about −24% or less shorter write delay, about −25% or less shorter write delay, about −26% or less shorter write delay, about −27% or less shorter write delay, about −28% or less shorter write delay, about −29% or less shorter write delay, or about −30% or less shorter write delay.

In another example, in a 32×32 SRAM array, the write delay for a far cell 632 of a FS-PDN SRAM cell and a BS-PDN SRAM cell may both be about equivalent at 50 ps. In a 64×64 SRAM array, the write delay for a far cell 632 of a FS-PDN SRAM cell can be about 60 ps while the write delay for a BS-PDN SRAM cell can be about 58.5 ps. In a 64×64 SRAM array, the write delay for a far cell 632 for a BS-PDN SRAM cell can have about −2% shorter write delay when compared to a FS-PDN SRAM cell. In a 128×128 SRAM array, the write delay for a far cell 632 of a FS-PDN SRAM cell can be about 90 ps while the write delay for a BS-PDN SRAM cell can be about 85 ps. In a 128×128 SRAM array, the write delay for a far cell 632 for a BS-PDN SRAM cell can have about −4% shorter write delay when compared to a FS-PDN SRAM cell. In a 256×256 SRAM array, the write delay for a far cell 632 of a FS-PDN SRAM cell can be about 225 ps while the write delay for a BS-PDN SRAM cell can be about 210 ps. In a 256×256 SRAM array, the write delay for a far cell 632 for a BS-PDN SRAM cell can have about −7% shorter write delay when compared to a FS-PDN SRAM cell. In some examples, the write delay for a far cell 632 for a BS-PDN SRAM cell of any size, when compared to an equivalent FS-PDN SRAM cell, can have about −7% or less shorter write delay, about −8% or less shorter write delay, about −9% or less shorter write delay, about −10% or less shorter write delay, about −11% or less shorter write delay, about −12% or less shorter write delay, about −13% or less shorter write delay, about −14% or less shorter write delay, about −15% or less shorter write delay, about −16% or less shorter write delay, about −17% or less shorter write delay, about -18% or less shorter write delay, about −19% or less shorter write delay, about −20% or less shorter write delay, about −21% or less shorter write delay, about −22% or less shorter write delay, about −23% or less shorter write delay, about −24% or less shorter write delay, about −25% or less shorter write delay, about −26% or less shorter write delay, about −27% or less shorter write delay, about −28% or less shorter write delay, about −29% or less shorter write delay, or about −30% or less shorter write delay.

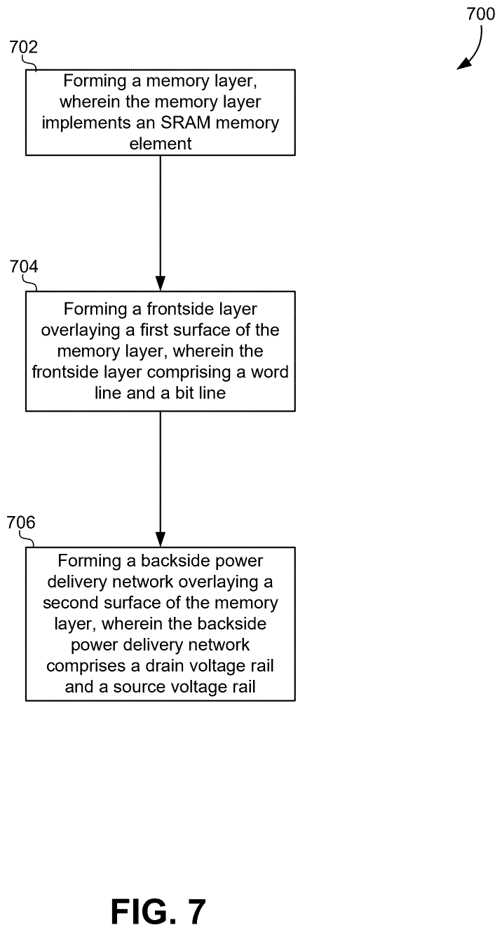

FIG. 7 illustrates a flowchart of exemplary operations in a method 700 of forming a semiconductor device with SRAM cells having backside power delivery networks according to some embodiments of the present technology. Method 700 may include one or more operations prior to the initiation of the method 700. Method 700 may include a number of optional operations, which may or may not be specifically associated with some embodiments of methods according to embodiments of the present technology.

It should be appreciated that the specific steps illustrated in FIG. 7 provide particular methods of designing and/or controlling the resistance for an interconnect between hybrid bonded structures according to various embodiments. Other sequences of steps may also be performed according to alternative embodiments. For example, alternative embodiments may perform the steps outlined above in a different order. Moreover, the individual steps illustrated in FIG. 7 may include multiple sub-steps that may be performed in various sequences as appropriate to the individual step. Furthermore, additional steps may be added or removed depending on the particular applications. Many variations, modifications, and alternatives also fall within the scope of this disclosure.

At operation 702, the method of flowchart 200 may include forming a memory layer (for example, the memory layer as described in relation to FIG. 3) of an SRAM cell. The memory layer can implement an SRAM memory element. The SRAM memory element can include multiple transistors and different layers and structures to implement those transistors. For example, the SRAM memory element can include n-doped regions, p-doped regions, channels, poly, and the like. Similarly, the SRAM memory element can include contacts. The contacts can be conductors used to connect different parts of the SRAM memory element to other parts of the SRAM cell. In some examples, forming the memory layer can include forming a first placeholder via that extends from a bottom of the SRAM memory element to a first contact of the contacts. In some examples, forming the memory layer can include forming a second placeholder via that extends from a bottom of the SRAM memory element to a second contact of the contacts.

At operation 704, the method of flowchart 200 may include forming a frontside layer (for example, the frontside layer as described in relation to FIG. 3) of the SRAM cell. The frontside layer can be formed to overlay a first surface of the memory layer (for example, the top layer of the memory layer). The frontside layer of the SRAM cell can include a word line and a bit line. In some examples, the frontside layer can include a bit line bar. The word line, bit line, and bit line bar can be connected to the top of the SRAM memory element.

At operation 706, the method of flowchart 200 may include forming a backside power delivery network (for example, the backside power delivery network as described in relation to FIG. 3) of the SRAM cell. The backside power delivery network can be formed to overlay a second surface of the memory layer (for example, the bottom layer of the memory layer or the opposite surface over which the frontside layer overlays the memory layer). The backside power delivery network can include a drain voltage rail and a source voltage rail connected to contacts of the SRAM memory element. In some examples, there can be two source voltage rails formed in the backside power delivery network. In some examples, forming the backside power delivery network can include forming a first via that extends from the source voltage rail to a first contact of the contacts. In some examples, forming the backside power delivery network can include forming a second via that extends from the drain voltage rail to a second contact of the contacts. In some examples, forming the backside power delivery network can include forming a first via to replace a first placeholder via. The first via can extend from the source voltage rail to a first contact of the contacts. In some examples, forming the backside power delivery network can include forming a second via to replace a second placeholder via. The second via can extend from the drain voltage rail to a second contact of the contacts.

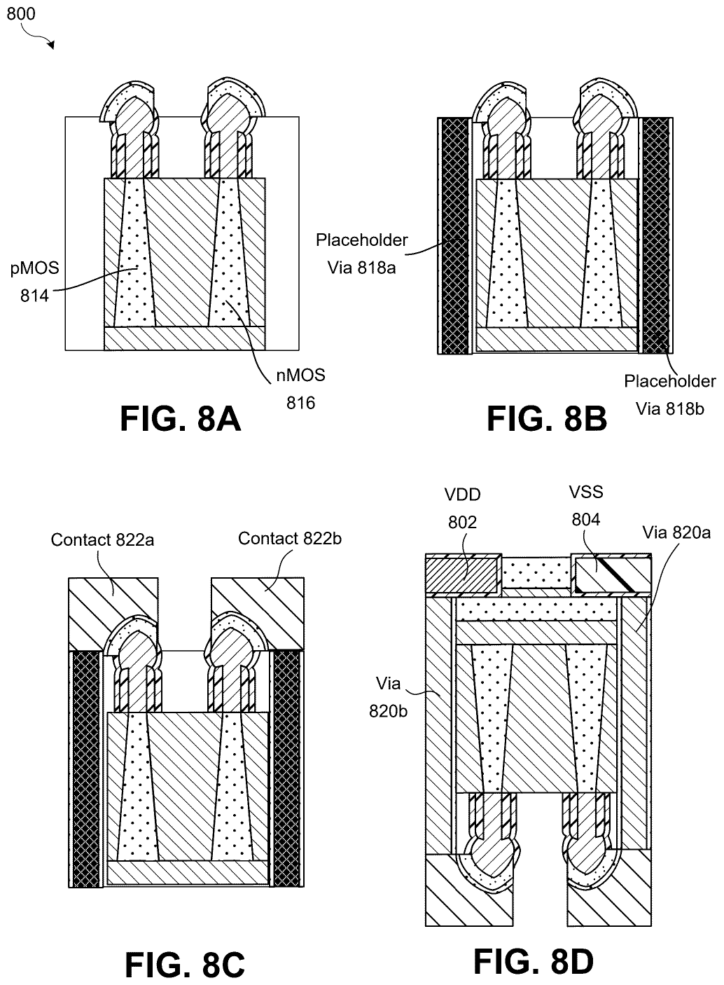

FIGS. 8A-8D illustrate exemplary schematic cross-sectional structures that can be produced during the at various points during the method 700 of FIG. 7. FIG. 8A illustrates a portion of the memory layer of the SRAM cell, focusing on the pMOS transistor 814 (for example, the pMOS transistor 314 of FIG. 3) and the nMOS transistors 816 (for example, the nMOS transistor 316 of FIG. 3). Not all structures shown in FIG. 8A need to be fully formed, etched, or deposited prior to advancing to the step described in relation to FIG. 8B.

In FIG. 8B, placeholder vias 818a, 818b are etched and/or deposited adjacent to the pMOS transistor 814 and nMOS transistor 816. The placeholder vias 818a, 818b can eventually be replaced by vias 820a, 820b as shown in FIG. 8D. The placeholder vias 818a, 818b can be used to ensure that the memory layer is mostly formed prior to the formation of the backside power delivery network. In FIG. 8C, the contacts 822a, 822b are formed over the placeholder vias 818a, 818b and the pMOS transistor 814 and nMOS transistor 816. Once the contacts 822a, 822b, the frontside layer (including the bit line and word line) can be etched and/or deposited onto the SRAM cell.

After the frontside layer has been etched and/or deposited, the backside power delivery network can be etched and/or deposited on the opposite side of the SRAM cell. For example, the SRAM cell can be flipped such that the previously-bottom side of the SRAM cell is now facing upward. The placeholder vias 818a, 818b can be etched using a selective etch to form the vias 820a, 820b. Then conductive material can be selectively deposited into the vias 820a, 820b. Then one or more dielectrics can be deposited onto the backside of the SRAM cell. Then the VDD 802 and VSS 804 can be deposited into the dielectrics.

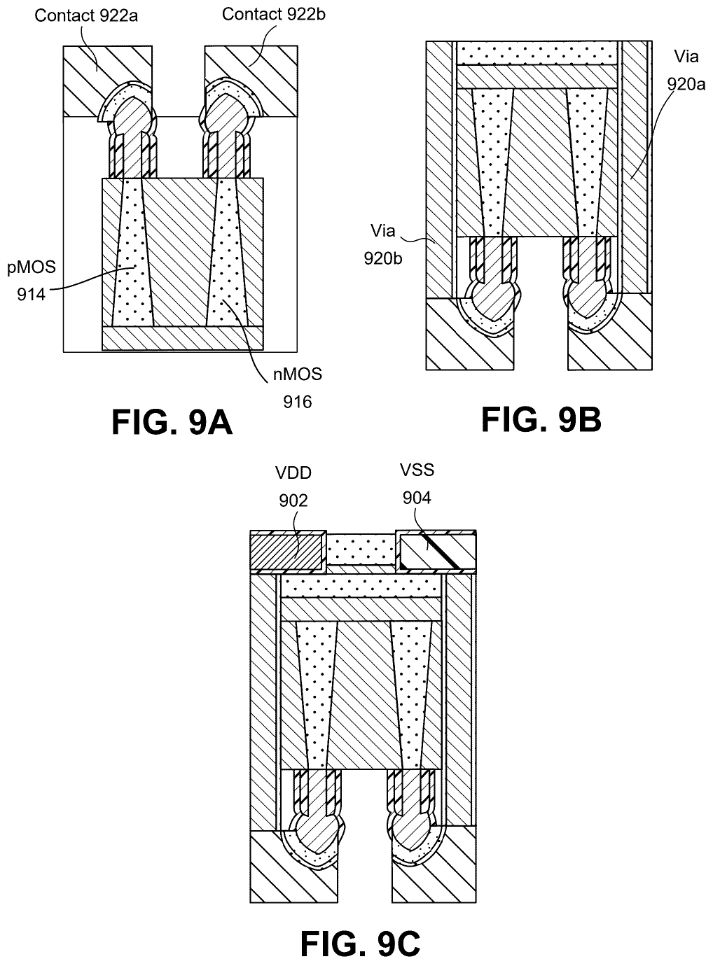

FIGS. 9A-9C illustrate exemplary schematic cross-sectional structures that can be produced during the at various points during the method 700 of FIG. 7. FIG. 9A illustrates a portion of the memory layer of the SRAM cell, focusing on the pMOS transistor 914 (for example, the pMOS transistor 314 of FIG. 3) and the nMOS transistors 916 (for example, the nMOS transistor 316 of FIG. 3). In this example, the memory layer (including the SRAM memory element) can be completely formed and the frontside layer can be formed on top of the SRAM memory element. In this way, the SRAM memory element can already have contacts 922a, 922b prior to the formation of the vias 920a, 920b, the VDD 902, and VSS 904.

After the memory layer and the frontside layer have been formed, the SRAM cell can be flipped over in order to form the backside power delivery network on the backside of the SRAM cell. Vias 920a, 920b can be selectively etched and deposited to connect to the contacts 922a, 922b. Additional layers of dielectrics can be deposited and etched onto the backside of the SRAM cell and then the VDD 902 and VSS 904 can be deposited. The vias 920a, 920b can connect the VDD 902 and VSS 904 to the contacts 922a, 922b.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A semiconductor device comprising:
one or more static random-access memory (SRAM) cells, wherein each SRAM cell includes:
a backside power delivery network comprising a drain voltage rail and a source voltage rail;
a memory layer overlaying the backside power delivery network, wherein the memory layer implements an SRAM memory element, and wherein the drain voltage rail and the source voltage rail are connected to contacts at a top of the SRAM memory element; and
a frontside layer overlaying the memory layer comprising a word line and a bit line that are connected to the top of the SRAM memory element.

2. The semiconductor device of claim 1, further comprising a first via that extends from the source voltage rail to a first contact of the contacts.

3. The semiconductor device of claim 2, further comprising a second via that extends from the drain voltage rail to a second contact of the contacts.

4. The semiconductor device of claim 3, wherein the first via and the second via are rectangular vias with a cross-sectional width of less than or about 20.0 nm.

5. The semiconductor device of claim 4, wherein the first via and the second via are square vias with a cross-sectional length of less than or about 20.0 nm.

6. The semiconductor device of claim 1, wherein a capacitance between the source voltage rail and the word line is between about 4.0 aF and about 80.0 aF.

7. The semiconductor device of claim 1, wherein a capacitance between the drain voltage rail and the word line is between about 1.0 aF and about 20.0 aF.

8. The semiconductor device of claim 1, wherein a capacitance between the source voltage rail and the bit line is between about 1.0 aF and about 10.0 aF.

9. The semiconductor device of claim 1, further comprising a bit line bar connected to contacts at a top of the SRAM memory element, wherein a capacitance between the source voltage rail and the bit line bar is between about 1.0 aF and about 10.0 aF.

10. The semiconductor device of claim 1, wherein the SRAM memory element includes at least six transistors.

11. A method of forming a semiconductor device comprising:
forming one or more static random-access memory (SRAM) cells, wherein forming each SRAM cell includes:
forming a memory layer, wherein the memory layer implements an SRAM memory element, wherein the SRAM memory element has contacts at a top of the SRAM memory element;
forming a frontside layer overlaying a first surface of the memory layer, wherein the frontside layer comprising a word line and a bit line that are connected to the top of the SRAM memory element; and
forming a backside power delivery network overlaying a second surface of the memory layer, wherein the backside power delivery network comprises a drain voltage rail and a source voltage rail that are connected to the contacts.

12. The method of claim 11 wherein forming the backside power delivery network comprises forming a first via that extends from the source voltage rail to a first contact of the contacts.

13. The method of claim 12 wherein forming the backside power delivery network comprises forming a second via that extends from the drain voltage rail to a second contact of the contacts.

14. The method of claim 11, wherein forming the memory layer comprises forming a first placeholder via that extends from a bottom of the SRAM memory element to a first contact of the contacts.

15. The method of claim 14 wherein forming the backside power delivery network comprises forming a first via to replace the first placeholder via, wherein the first via extends from the source voltage rail to a first contact of the contacts.

16. The method of claim 14, wherein the first via is a rectangular via with a cross-sectional width of less than or about 20.0 nm.

17. The method of claim 11, wherein a capacitance between the source voltage rail and the word line is less than or about 10.0 aF.

18. A semiconductor device comprising:
one or more static random-access memory (SRAM) cells, wherein each SRAM cell includes:
a backside power delivery network comprising a drain voltage rail and a source voltage rail;
a memory layer overlaying the backside power delivery network, wherein the memory layer implements an SRAM memory element, and the drain voltage rail and the source voltage rail are connected to the SRAM memory element and provide power to the SRAM memory element; and
a frontside layer overlaying the memory layer comprising a word line and a bit line that are connected to a top of the SRAM memory element.

19. The semiconductor device of claim 18, further comprising a first via that extends from the source voltage rail to the SRAM memory element.

20. The semiconductor device of claim 18, wherein a capacitance between the drain voltage rail and the word line is less than or about 5.0 aF.
